(19) United States
(12) Patent Application Publication
(10) Pub. No.: US 2016/0141453 A1
(43) Pub. Date: May 19, 2016

(54) LATTICE-MATCHED LIGHT EMITTING ELEMENT

(71) Applicant: NATIONAL SUN YAT-SEN UNIVERSITY, Kaohsiung (TW)

(72) Inventors: I-Kai Lo, Kaohsiung (TW); Ying-Chieh Wang, Kaohsiung (TW); Yu-Chi Hsu, Kaohsiung (TW); Cheng-Hung Shih, Kaohsiung (TW)

(21) Appl. No.: 14/584,523

(22) Filed: Dec. 29, 2014

(30) Foreign Application Priority Data
Nov. 19, 2014 (TW) 103140122

(51) Int. Cl. H01L 33/24; H01L 33/44; H01L 33/40; H01L 33/00; H01L 33/32

(52) U.S. Cl. CPC H01L 33/24; H01L 33/0075; H01L 33/32; H01L 33/40; H01L 33/44; H01L 2933/0016; H01L 2933/0025

(57) ABSTRACT

A light emitting element and its manufacturing method are disclosed. A larger end face of a gallium nitride pyramid contacts with a mounting face of a gallium nitride layer disposed on a substrate, with c-axes of the gallium nitride layer and the gallium nitride pyramid coaxial to each other, and with M-planes of the gallium nitride layer and the gallium nitride pyramid parallel to each other. Broken bonds at contact faces of the gallium nitride pyramid and of the gallium nitride layer weld with each other after heating and cooling. A portion of an insulating layer coated on the gallium nitride pyramid and is removed to form an electrically conductive portion on which a first electrode is disposed. A portion of the insulating layer coated on the gallium nitride layer is removed to form another electrically conductive portion on which a second electrode is disposed.

### BACKGROUND OF THE INVENTION

1. Field of the Invention

The present invention relates to a light emitting element and a method for manufacturing the light emitting element and, more particularly, to a lattice-matched light emitting element and a method for manufacturing the light emitting element.

2. Description of the Related Art

Due to progress of the semiconductor technology, light emitting elements, such as light-emitting diodes, made by solid-state element technology have gradually been developed and can be used in illumination, display, or measurement while having the advantages of saving electricity and long service life.

The material (such as gallium nitride) for conventional solid-state light emitting element is generally produced by thin film technology, an example of which has been disclosed by Martin F. Schubert, Sameer Chhajed, Jong Kyu Kim, and E. Fred Schubert, Daniel D. Koleske, Mary H. Crawford, Stephen R. Lee, Archur J. Fischer, Gerald Thaler, and Michael A. Banas (“Effect of dislocation density on efficiency drop in GaInN/GaN light-emitting diodes”, APPLIED PHYSICS LETTERS 91, 231114 (2007)). However, the manufacturing method often generates a large amount of epitaxial defects due to lattice mismatch, leading to poor light emitting efficiency and poor stability. Thus, it is difficult to manufacture light emitting element products with high quality and uniformity.

To solve the defects resulting from the above thin film technology, manufacturing methods using a single crystal structure have gradually been adopted, and an example of which has been disclosed by Zhaohui Zhong, Fang Qian, Deli Wang, and Charles M. Lieber (“Synthesis of p-Type Gallium Nitride Nanawires for Electronic and Photonic Nanodevices”, 2003 American Chemical Society, Published on Web Feb. 20, 2003). However, the manufacturing methods for the nanoscale single crystal structure are more difficult and, thus, face problems in mass production and commercialization.

Thus, it is necessary to solve the above drawbacks in the prior art to meet practical needs, thereby increasing the utility.

### SUMMARY OF THE INVENTION

The primary objective of the present invention is to provide a method for manufacturing a lattice-matched light emitting element.

Another objective of the present invention is to provide a lattice-matched light emitting element.

A method for manufacturing a light emitting element according to the present invention includes disposing a gallium nitride layer on a substrate and preparing a gallium nitride pyramid having a larger end face and a smaller end face. The larger end face of the gallium nitride pyramid contacts with a mounting face of the gallium nitride layer, with a c-axis of the gallium nitride layer coaxial to a c-axis of the gallium nitride pyramid, and with an M-plane of the gallium nitride layer parallel to an M-plane of the gallium nitride pyramid. Temperatures of the gallium nitride layer and the gallium nitride pyramid are increased and then reduced. Broken bonds at the larger end face of the gallium nitride pyramid and the mounting face of the gallium nitride layer weld with each other. An insulating layer is coated on faces of the gallium nitride layer and the gallium nitride pyramid. A portion of the insulating layer on the faces of the gallium nitride pyramid is removed to form an electrically conductive portion on the gallium nitride pyramid. A first electrode is disposed on the electrically conductive portion of the gallium nitride pyramid. A portion of the insulating layer on the faces of the gallium nitride layer is removed to form an electrically conductive portion on the gallium nitride layer. A second electrode is disposed on the electrically conductive portion of the gallium nitride layer.

The temperatures of the gallium nitride layer and the gallium nitride pyramid can be increased to 550-750° C. and then reduced to 25° C. to make the broken bonds at the larger end face of the gallium nitride pyramid and the mounting face of the gallium nitride layer welding with each other.

The temperatures of the gallium nitride layer and the gallium nitride pyramid can be increased and then kept at the increased temperatures for a period of time before reducing the temperatures of the gallium nitride layer and the gallium nitride pyramid.

The gallium nitride layer grows in [0001] direction of a four-axis coordinate system. The gallium nitride pyramid grows in [0001̅] direction of the four-axis coordinate system and forms a prism and a pyramid.

The insulating layer can be an oxidation layer.

The oxidation layer can contain aluminum oxide or silicon oxide.

The insulating layer can have a thickness of 200-300 nm.

The first electrode can be made of titanium, aluminum, titanium-aluminum alloy, titanium-nickel alloy, or titanium-aluminum-nickel-gold alloy.

The second electrode can be made of nickel-platinum alloy, nickel-gold alloy, or nickel-platinum-gold alloy.

A light emitting element according to the present invention includes a gallium nitride layer having a mounting face. A gallium nitride pyramid includes a smaller end face and a larger end face. The larger end face of the gallium nitride pyramid contacts with the mounting face of the gallium nitride layer. The c-axis of the gallium nitride layer coaxial to the c-axis of the gallium nitride pyramid. The M-plane of the gallium nitride layer parallel to the M-plane of the gallium nitride pyramid. Broken bonds at the mounting face of the gallium nitride layer and the larger end face of the gallium nitride pyramid weld with each other. An insulating layer is coated on faces of the gallium nitride layer and the gallium nitride pyramid. A portion of the gallium nitride pyramid is exposed outside of the insulating layer to form an electrically conductive portion. A portion of the gallium nitride layer is exposed outside of the insulating layer to form an electrically conductive portion. A first electrode is electrically connected to the electrically conductive portion of the gallium nitride pyramid. A second electrode is electrically connected to the electrically conductive portion of the gallium nitride layer.

The light emitting element as claimed in claim 11, wherein the insulating layer is an oxidation layer.

The oxidation layer can contain aluminum oxide or silicon oxide.

The insulating layer can have a thickness of 200-300 nm.

The first electrode can be made of titanium, aluminum, titanium-aluminum alloy, titanium-nickel alloy, or titanium-aluminum-nickel-gold alloy.

The second electrode can be made of nickel-platinum alloy, nickel-gold alloy, or nickel-platinum-gold alloy.

The gallium nitride layer grows in [0001] direction of the four-axis coordinate system.

The gallium nitride pyramid grows in [0001̅] direction of the four-axis coordinate system.

In the above light emitting element and its manufacturing method, by contacting the large end face of the gallium nitride pyramid with the mounting face of the gallium nitride layer, with the c-axis of the gallium nitride pyramid coaxial to the c-axis of the gallium nitride layer and with the M-plane of the gallium nitride pyramid parallel to the M-plane of the gallium nitride layer, the broken bonds at the large end face of the gallium nitride pyramid and the mounting face of the gallium nitride layer weld with each other, such that the gallium nitride layer and the gallium nitride pyramid of the light emitting element tightly bond with each other to match the lattice of the gallium nitride layer with the lattice of the gallium nitride pyramid, avoiding epitaxial defects in the light emitting element while reinforcing the bonding between the gallium nitride layer and the gallium nitride pyramid to increase the bonding effect, thereby permitting smooth flow of electrons to enhance the electroluminescence effect. The effects of increasing the light emitting efficiency and improving the light emitting stability can, thus, be achieved.

The present invention will become clearer in light of the following detailed description of illustrative embodiments of this invention described in connection with the drawings.

### BRIEF DESCRIPTION OF THE DRAWINGS

The illustrative embodiments may best be described by reference to the accompanying drawings where:

FIG. 1 is a block diagram illustrating an embodiment of a method for manufacturing a light emitting element according to the present invention.

FIG. 2a is a cross sectional view illustrating a preparation step of the embodiment of the method for manufacturing a light emitting element according to the present invention.

FIG. 2b is a cross sectional view illustrating an alignment step of the embodiment of the method for manufacturing the light emitting element according to the present invention.

FIG. 2c is a cross sectional view illustrating a welding step of the embodiment of the method for manufacturing the light emitting element according to the present invention.

FIG. 2d is a cross sectional view illustrating an insulating step of the embodiment of the method for manufacturing the light emitting element according to the present invention.

FIG. 2e is a cross sectional view illustrating an exposing step of the embodiment of the method for manufacturing the light emitting element according to the present invention.

FIG. 2f is a cross sectional view illustrating an enveloping step of the embodiment of the method for manufacturing the light emitting element according to the present invention.

FIG. 2g is a cross sectional view illustrating a revealing step of the embodiment of the method for manufacturing the light emitting element according to the present invention.

FIG. 2h is a cross sectional view illustrating a filling step of the embodiment of the method for manufacturing the light emitting element according to the present invention.

FIG. 3a is a diagrammatic view illustrating the growing direction of a gallium nitride layer in the embodiment of the method for manufacturing a light emitting element according to the present invention.

FIG. 3b is a diagrammatic view illustrating the growing direction of a gallium nitride pyramid the embodiment of the method for manufacturing a light emitting element according to the present invention.

FIG. 3c is an image of a sample group of gallium nitride pyramids produced by the embodiment of the method for manufacturing a light emitting element according to the present invention.

FIG. 3d is a diagrammatic view illustrating alignment of the gallium nitride layer and the gallium nitride pyramid in the embodiment of the method for manufacturing a light emitting element according to the present invention.

FIG. 3e is a diagrammatic view illustrating mutual welding between broken bonds at contact faces of the gallium nitride layer and the gallium nitride pyramid in the embodiment of the method for manufacturing a light emitting element according to the present invention.

FIG. 4 is a cross sectional view of an embodiment of a light-emitting element of the present invention.

FIG. 5a is a current-voltage diagram of the embodiment of the light emitting element according to the present invention.

FIG. 5b is another current-voltage diagram of the embodiment of the light emitting element according to the present invention.

FIG. 6a is a scanning electron microscope (SEM) image of a gallium nitride pyramid and a gallium nitride layer of a sample of the embodiment of the light emitting element according to the present invention.

FIG. 6b is a transmission electron microscope (TEM) image of the interfaces of the gallium nitride pyramid and the gallium nitride layer of the sample.

FIG. 6c is an enlarged image of the interfaces.

FIG. 6d is an image showing the measurement result of a gallium nitride pyramid of the sample.

FIG. 6e is an image showing mismatch of the lattice directions of the gallium nitride pyramid and the gallium nitride pyramid of the SAD sample having the same incident direction as the incident direction shown in FIG. 6d and FIG. 6f.

FIG. 6f is an image showing the measurement result of the gallium nitride layer.

FIGS. 7a-7c are electron microscope images of a gallium nitride pyramid of another sample of the embodiment of the light emitting element according to the present invention.

FIG. 7d is an image of the gallium nitride pyramid.

FIG. 7e is an image of the sample after deposited with a 300 nm SiO₂ layer to serve as an insulating layer for n-type and p-type electrodes.

FIGS. 7f and 7g are images of the sample covered by the deposited SiO₂ layer.

FIG. 7h is an image of the sample with the electrode having an exposed upper portion.

FIG. 8a is an electron microscope image of a completed gallium nitride pyramid of a further sample of the embodiment of the light emitting element according to the present invention.

FIG. 8b is a transmission electron microscope (TEM) image of the sample.

FIGS. 8c and 8d are enlarged images of FIG. 8a.

FIGS. 8e-8i are high-resolution atomic images of the interfaces of a gallium nitride pyramid and a gallium nitride layer of the sample.

FIG. 8j is the diffraction pattern of the gallium nitride pyramid.

FIG. 8k is the diffraction pattern at the interfaces of the gallium nitride pyramid and the gallium nitride layer.

FIG. 8l is a diffraction pattern of the gallium nitride layer.

The present invention will become clearer in light of the following detailed description of illustrative embodiments of this invention described in connection with the drawings.

### DETAILED DESCRIPTION OF THE INVENTION

The term “self-assembling” referred to herein means directly modulating the growth parameters (such as growth temperature, growing time, or element ratio) of a molecular beam epitaxial system during epitaxy of the element by molecular beam epitaxy to obtain the desired shape, structure, and constitution of the element without conducting any processing procedure (such as yellow light lithography and etching) on the substrate of the epitaxy, which can be appreciated by one having ordinary skill in the art.

The term “hexagonal frustum” referred to herein means a hexagonal pyramid originally having an apex and a bottom face is cut to remove the apex, with two opposite ends of the hexagonal pyramid respectively forming a cut end and a connection end. Each of the cut end and the connection end is hexagonal. An area of the cut end is smaller than that of the connection end, which can be appreciated by one having ordinary skill in the art.

The term “wurtzite” referred to herein means a mineral structure of a hexagonal system, wherein the c-axis of the mineral structure is the [000-1] direction of a 4-axis coordinate system, which can be appreciated by one having ordinary skill in the art.

The term “semiconductor” referred to herein means a material having a controllable conductivity in a range between a conductor and an insulating member (namely, the band gap is larger than 9 eV), such as silicon (Si), germanium (Ge), or gallium arsenide (GaAs), which can be appreciated by one having ordinary skill in the art.

The term “electroluminescence effect” referred to herein means combination of an electron and a hole in a p-n junction of a light-emitting diode (LED) to emit light beams while an electric current flows through the p-n junction of the light-emitting diode, which can be appreciated by one having ordinary skill in the art.

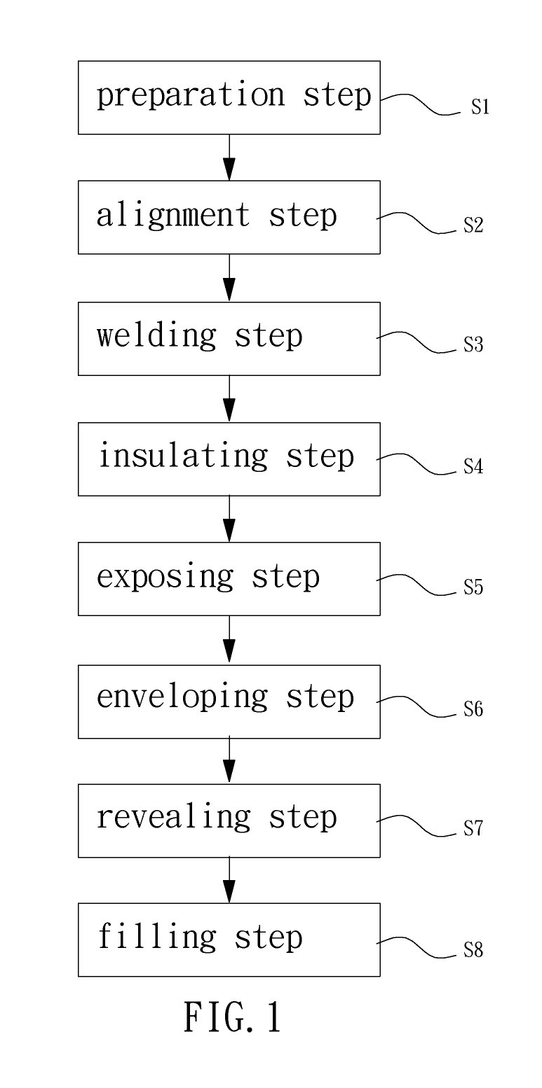

FIG. 1 is a block diagram illustrating an embodiment of a method for manufacturing a light emitting element according to the present invention. The embodiment of the method can be conducted in a reaction chamber to proceed with a preparation step S1, an alignment step S2, a welding step S3, an insulating step S4, an exposing step S5, an enveloping step S6, a revealing step S7, and a filling step S8.

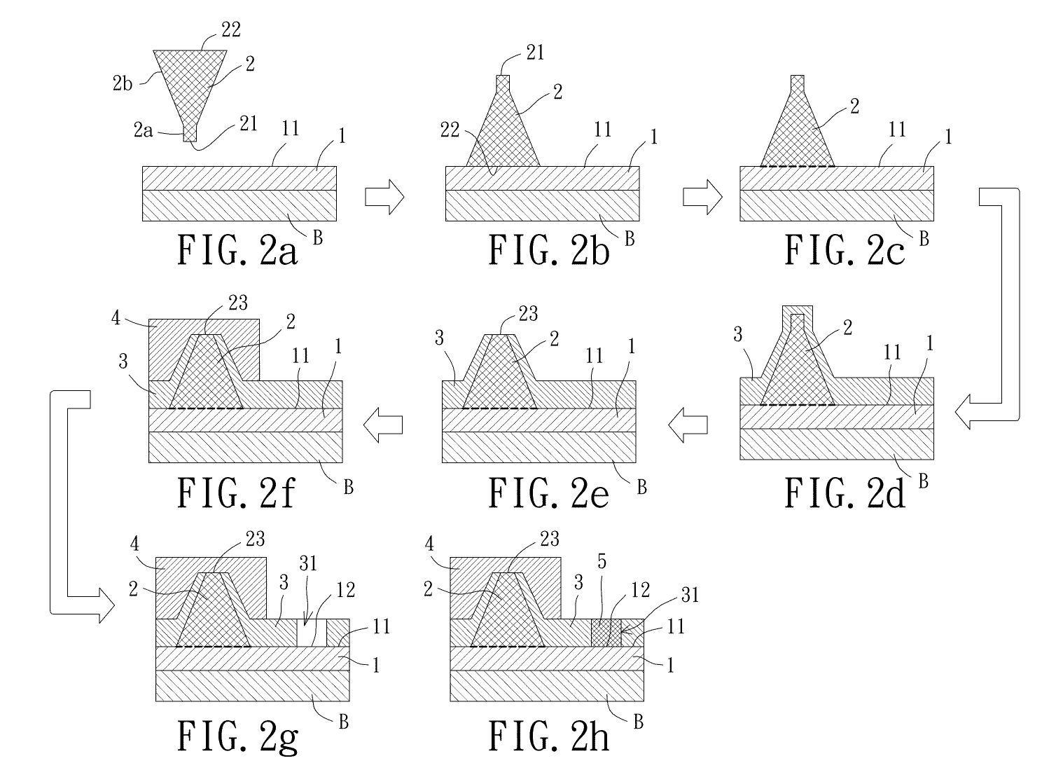

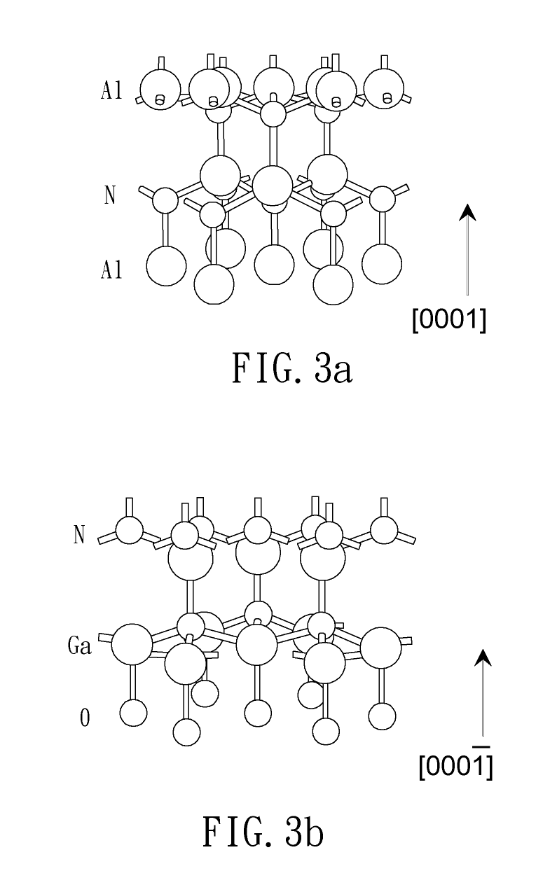

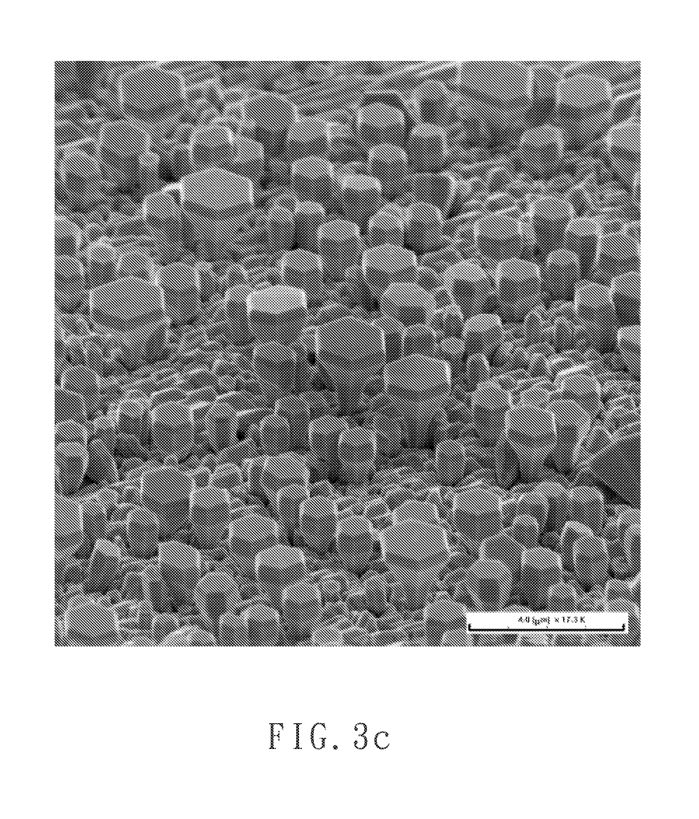

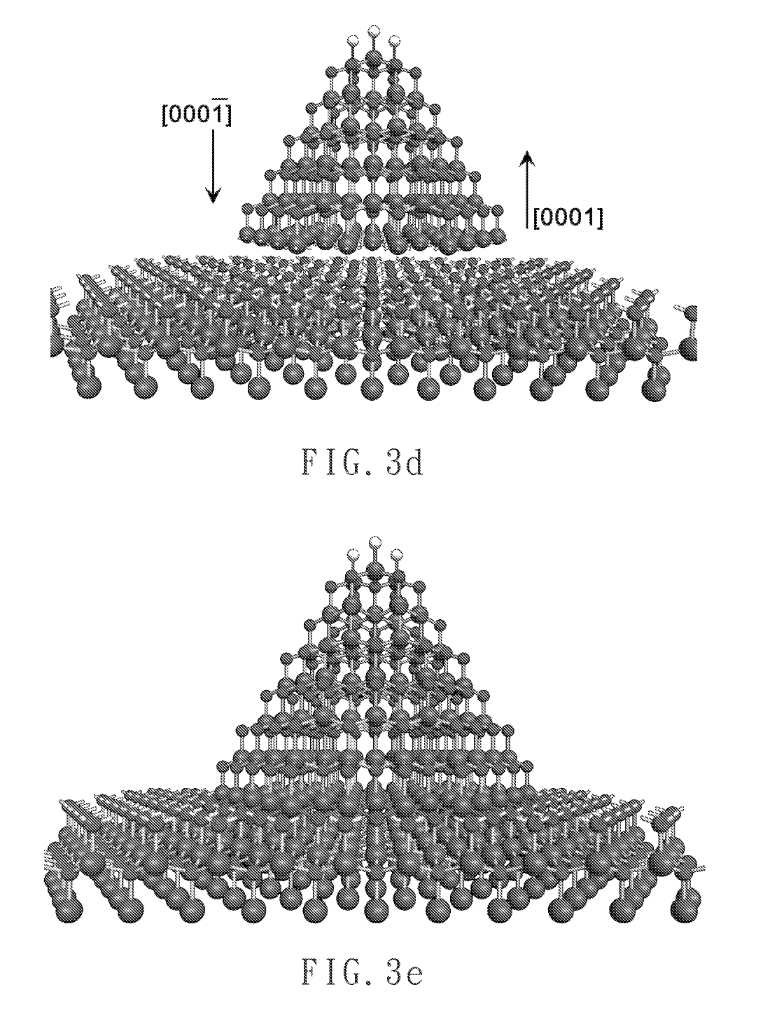

With reference to FIGS. 2a-2h, in the preparation step S1 a gallium nitride layer 1 is disposed on a substrate B and includes a mounting face 11. Furthermore, a gallium nitride pyramid 2 is prepared and includes a smaller end face 21 and a larger end face 22. As can be seen from FIG. 2a, in this embodiment, the substrate B can be an aluminum nitride (AlN) substrate or a sapphire substrate for deposition of the gallium nitride layer 1, such as by, but not limited to, epitaxial technology. The gallium nitride layer 1 grows in the [0001] direction of a four-axis coordinate system (see FIG. 3a). The mounting face 11 of the gallium nitride layer 1 can be cleaned first to remove impurities from the surface. The gallium nitride pyramid 2 grows in the [0001̅] direction of the four-axis coordinate system (see FIG. 3b) and forms a prism 2a and a pyramid 2b (the sample of which is shown in FIG. 3c and is in the form of a hexagonal frustum). A non-restrictive example of the preparation step S1 is disclosed in U.S. Pat. No. 8,728,235 B2.

In the alignment step S2 the larger end face 22 of the gallium nitride pyramid 2 contacts with the mounting face 11 of the gallium nitride layer 1. The c-axis of the gallium nitride layer 1 is coaxial to the c-axis of the gallium nitride pyramid 2. The M-plane of the gallium nitride layer 1 is parallel to the M-plane of the gallium nitride pyramid 2. As can be seen from FIG. 2b, in this embodiment, a robot arm (not shown) can be used to remove the gallium nitride pyramid 2 from a wafer in FIG. 3a, and the wafer is processed through an electron microscope or an image processing device to make the larger end face 22 of the gallium nitride pyramid 2 contact with the mounting face 11 of the gallium nitride layer 1, with the c-axis of the gallium nitride layer 1 coaxial to the c-axis of the gallium nitride pyramid 2 and with the M-plane of the gallium nitride layer 1 parallel to an M-plane of the gallium nitride pyramid 2. Thus, the lattices of the gallium nitride layer 1 and the gallium nitride pyramid 2 match with each other (see FIG. 3d). The gallium nitride layer 1 and the gallium nitride pyramid 2 are used as a P-type semiconductor and an N-type semiconductor respectively. Each of the gallium nitride layer 1 and the gallium nitride pyramid 2 includes a hexagonal lattice having a lattice structure similar to that of a hexagonal prism. The c-axis direction (the [0001] direction) is the extending direction of the hexagonal prism, and the M-plane is the six faces of the hexagonal prism, which can be appreciated by one having ordinary skill in the art.

In the welding step S3 temperatures of the gallium nitride layer 1 and the gallium nitride pyramid 2 are increased and then reduced to make the broken bonds at the larger end face 22 of the gallium nitride pyramid 2 and the mounting face 11 of the gallium nitride layer 1 weld with each other. As can be seen from FIG. 2c, in this embodiment, in order to weld the gallium nitride pyramid 2 with the gallium nitride layer 1, an annealing process can be carried out (such as heating the gallium nitride pyramid 2 and the gallium nitride layer 1 at a temperature increasing speed (such as 20° C./sec) to a high temperature (such as 550-750° C., e.g., 700° C.), keeping at the high temperature for a period of time (such as 15 minutes), and then naturally cooling the gallium nitride layer 1 and the gallium nitride pyramid 2 to a low temperature (such as 25° C.)) to make the broken bonds at the larger end face 22 of the gallium nitride pyramid 2 and the mounting face 11 of the gallium nitride layer 1 weld with each other (see FIG. 3e), permitting tight bonding between gallium nitride pyramid 2 and the gallium nitride layer 1, thereby making the lattices of the gallium nitride layer 1 and the gallium nitride pyramid 2 match with each other and thereby improving the bonding between the gallium nitride layer 1 and the gallium nitride pyramid 2. The pressure of the reaction chamber (not shown) can be adjusted to be lower than 9×10⁻⁶ ton during the annealing process.

In the insulating step S4 an insulating layer 3 is coated on the faces of the gallium nitride layer 1 and the gallium nitride pyramid 2 to isolate the P-type semiconductor and the N-type semiconductor. As can be seen from FIG. 2d, in this embodiment, the insulating layer 3 can be deposited on the faces of the gallium nitride layer 1 and the gallium nitride pyramid 2. The insulating layer 3 can be an oxidation layer, such as an insulating material containing aluminum oxide (Al₂O₃) or silicon oxide (SiO₂). The insulating layer 3 can have a thickness of 200-300 nm to provide an appropriate insulating effect. However, the present invention is not limited to this example.

In the exposure step S5 a portion of the insulating layer 3 on the faces of the gallium nitride pyramid 2 is removed to form an electrically conductive portion 23 at the exposed portion of the gallium nitride pyramid 2. As can be seen from FIG. 2e, in this embodiment, a portion of the insulating layer 3 on the smaller end face 21 and an outer face of the gallium nitride pyramid 2 can be removed by grinding or cutting. Alternatively, only a portion of the insulating layer 3 on the smaller end face 21 is removed to expose a portion of the gallium nitride pyramid 2, forming the electrically conductive portion 23. However, the present invention is not limited to these examples.

In the enveloping step S6 a first electrode 4 is disposed on the electrically conductive portion 23 of the gallium nitride pyramid 2 to electrically connect the gallium nitride pyramid 2 to an external power source (not shown). As can be seen from FIG. 2f, in this embodiment, the first electrode 4 can be disposed on the electrically conductive portion 23 by deposition or epitaxy. In addition to contacting with the electronically conductive portion 23, the first electrode 4 can further cover the protruded portion of the gallium nitride pyramid 2 to protect the gallium nitride pyramid 2. The first electrode 4 can be made of titanium, aluminum, titanium-aluminum (Ti/Al) alloy, titanium-nickel (Ti/Ni) alloy, or titanium-aluminum-nickel-gold (Ti/Al/Ni/Au) alloy.

In the revealing step S7 a portion of the insulating layer 3 on the faces of the gallium nitride layer 1 is removed to form another electrically conductive portion 12 at the revealed portion of the gallium nitride layer 1. As can be seen from FIG. 2g, in this embodiment, a portion of the insulating layer 3 above a portion of the gallium nitride layer 1 not covered by the gallium nitride pyramid 2 can be removed to form a hole 31 to thereby reveal the gallium nitride layer 1 and to thereby form the electrically conductive portion 12. However, the present invention is not limited to this example.

In the filling step S8 a second electrode 5 is disposed on the electrically conductive portion 12 of the gallium nitride layer 1 such that the gallium nitride layer 1 can be electrically connected to an external power source (not shown). As can be seen from FIG. 2h, in this embodiment, the second electrode 5 can be produced by deposition or epitaxy. The second electrode 5 can be made of a conductive material, such as nickel-platinum (Ni/Pt) alloy, nickel-gold (Ni/Au) alloy, or nickel-platinum-gold (Ni/Pt/Au) alloy to provide an appropriate electrical connection. However, the present invention is not limited to this example.

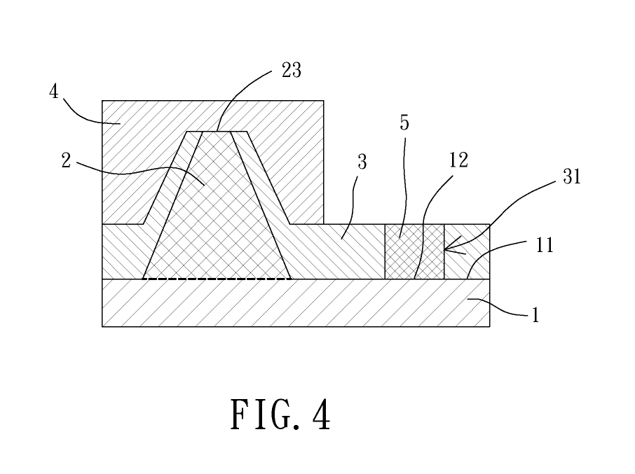

By the above steps, the method for manufacturing a light emitting element according to the present invention can be used to manufacture an embodiment of a light emitting element (FIG. 4) according to the present invention. The embodiment of the light emitting element includes a gallium nitride layer 1, a gallium nitride pyramid 2, an insulating layer 3, a first electrode 4, and a second electrode 5. The mounting face 11 of the gallium nitride layer 1 contacts with the larger end face 22 of the gallium nitride pyramid 2. The c-axis of the gallium nitride layer 1 is coaxial to the c-axis of the gallium nitride pyramid 2. The M-plane of the gallium nitride layer 1 is parallel to the M-plane of the gallium nitride pyramid 2. The broken bonds at the mounting face 11 of the gallium nitride layer 1 and the larger end face 22 of the gallium nitride pyramid 2 weld with each other. The insulating layer 3 is coated on faces of the gallium nitride layer 1 and the gallium nitride pyramid 2. The first electrode 4 is electrically connected to the electrically conductive portion 23 formed by a portion of the gallium nitride pyramid 2 exposed outside of the insulating layer 3. The second electrode 5 is electrically connected to the electrically conductive portion 12 formed by a portion of the gallium nitride layer 1 exposed outside of the insulating layer 3.

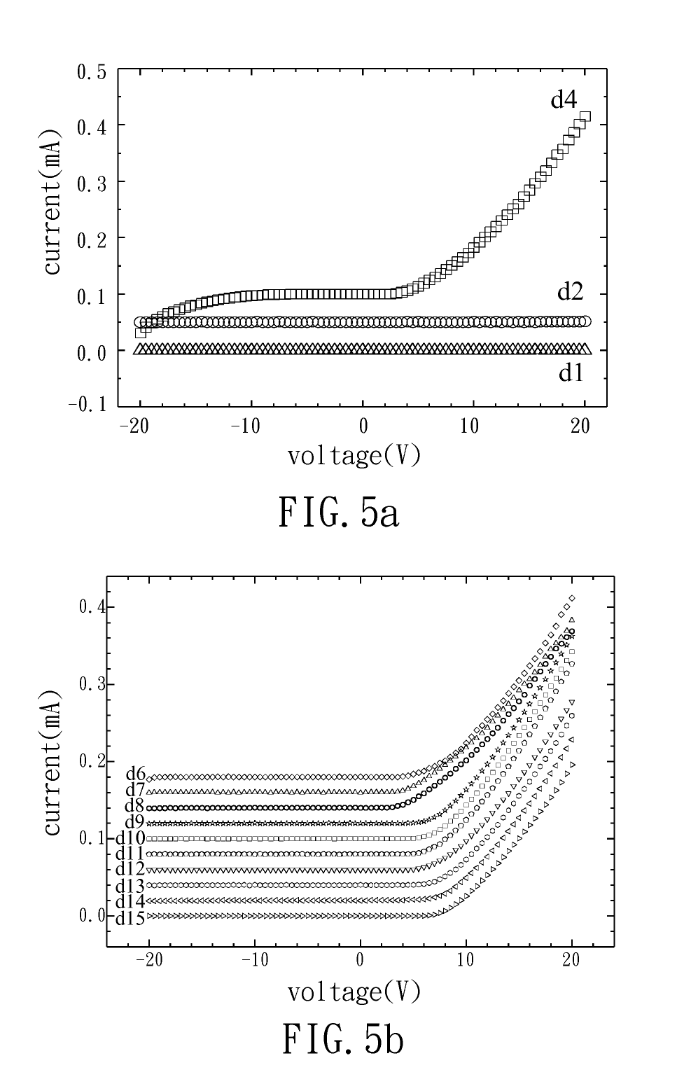

FIGS. 5a and 5b are current-voltage diagrams of the embodiment of the light emitting element according to the present invention. Fifteen gallium nitride pyramids of the same wafer of FIG. 5 were used as the test targets (No. d1-d15). Voltages in a range between −20V and +20V were applied to the first and second electrodes 4 and 5 shown in FIG. 4. As can be seen from

FIGS. 5a and 5b, current-voltage curves of a light emitting element can be found in the current-voltage curves of most of the gallium nitride pyramids, wherein the measured resistance was about 45 KΩ, and the critical voltage was about 5.9V.

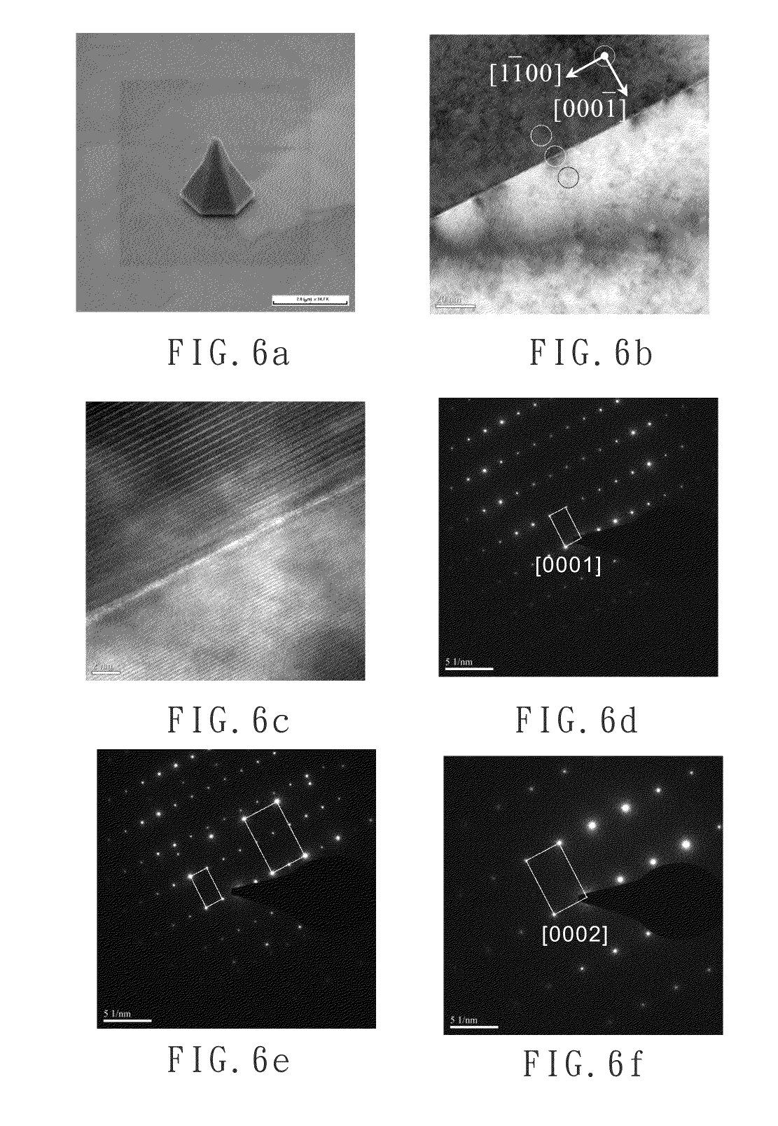

FIGS. 6a-6f are images of structure analysis of a sample of the embodiment of the light emitting element according to the present invention, wherein the images were obtained from No. d3 gallium nitride pyramid example. Specifically, FIG. 6a is a scanning electron microscope (SEM) image of the gallium nitride pyramid and the gallium nitride layer after annealing at about 700° C. FIG. 6b is a transmission electron microscope (TEM) image of the interfaces of the gallium nitride pyramid and the gallium nitride layer taken in the incident direction [112̅0]. FIG. 6c is an enlarged image of the interfaces, wherein the gap between the gallium nitride pyramid and the gallium nitride layer can clearly be seen in the high-resolution TEM image, and wherein selected area diffraction (SAD) was used to obtain an area surrounding the interfaces in FIG. 6b to analyze the TEM sample. FIG. 6d is an image showing the measurement result of the gallium nitride pyramid in the incident direction [112̅0]. FIG. 6f is an image showing the measurement result of the gallium nitride layer in the incident direction [112̅0]. FIG. 6e is an image showing mismatch of the lattice directions of the gallium nitride pyramid and the gallium nitride pyramid of the SAD sample having the same incident direction as the incident direction shown in FIG. 6d and FIG. 6f. Thus, as can be seen from this sample, the current-voltage curve of a light emitting element cannot be successfully measured if the lattice directions of the gallium nitride pyramid and the gallium nitride layer do not match with each other.

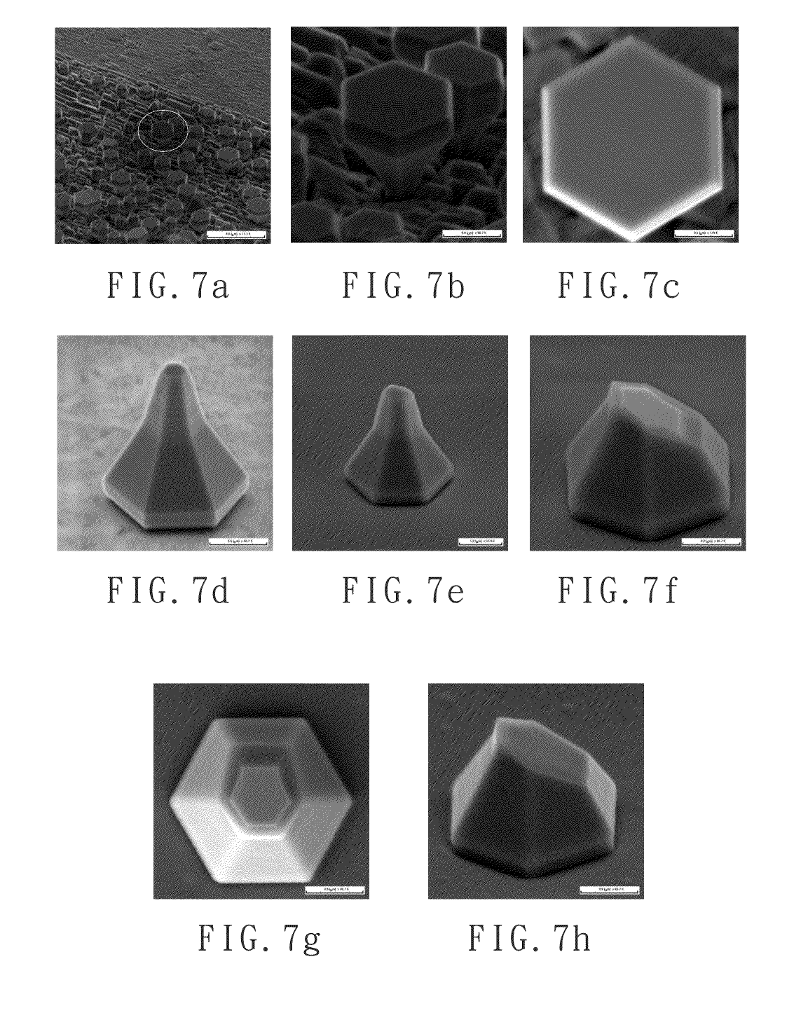

FIGS. 7a-7h are images of surface measurement of another sample of the embodiment of the light emitting element according to the present invention, wherein the images were obtained from No. d10 gallium nitride pyramid example. FIGS. 7a, 7b and 7c are the electron microscope images of the gallium nitride pyramid of the light emitting element. As can be seen from the appearance of the regular hexagon, the gallium nitride pyramid has a high-quality single crystal structure. FIG. 7d is an image of the gallium nitride pyramid, wherein the gallium nitride pyramid was removed independently, was invertedly disposed on a p-type gallium nitride layer, and was annealed at 700° C. to weld the contact faces of the gallium nitride pyramid and the gallium nitride layer. FIG. 7e is an image of the sample after deposited with a 300 nm SiO₂ layer to serve as an insulating layer for the n-type electrode and the p-type electrode. FIGS. 7f and 7g are images of the sample covered by the deposited SiO₂ layer, wherein a portion of the insulating layer on top of the gallium nitride pyramid and a portion of the tail of the gallium nitride pyramid are removed to expose an upper portion of an electrode. FIG. 7h is an image of the sample with the electrode having an exposed upper portion, wherein a layer of titanium having a thickness of about 30 nm was deposited to serve as an upper electrode.

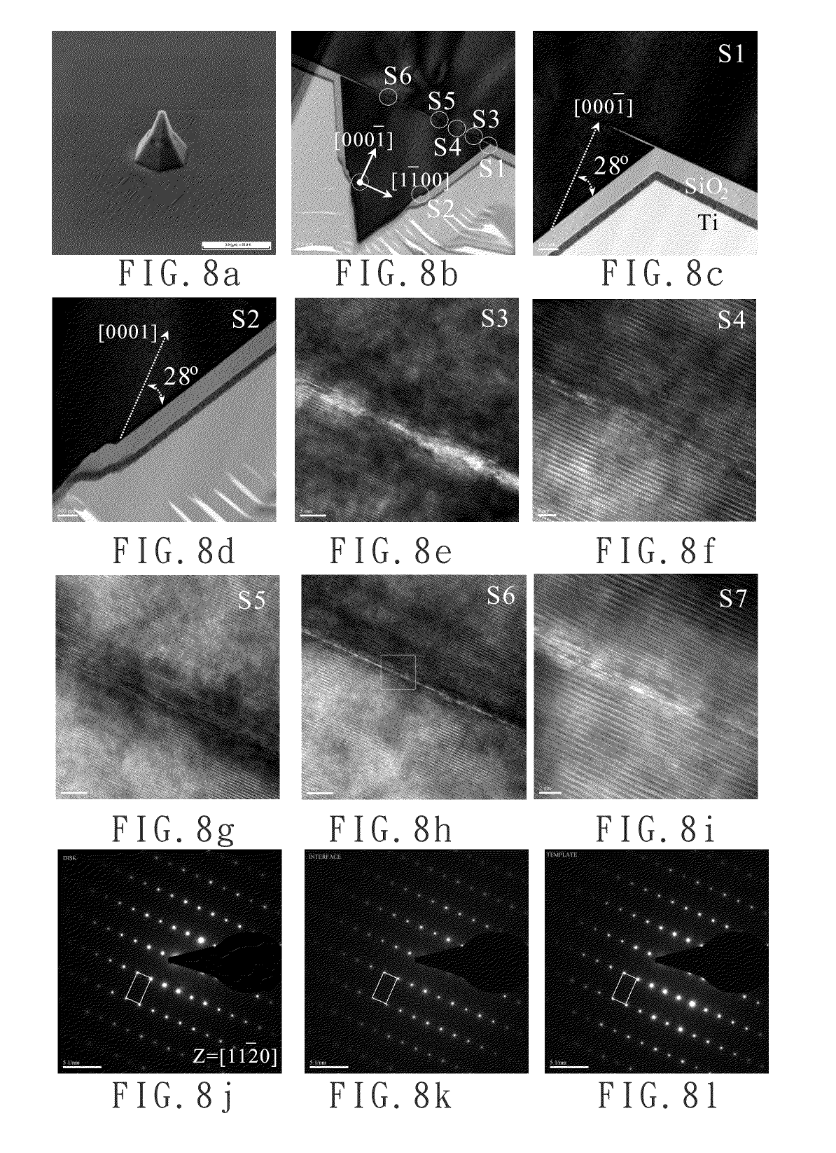

FIGS. 8a-8l are images of structure analysis of a further sample of the embodiment of the light emitting element according to the present invention, wherein the images were obtained from No. d5 gallium nitride pyramid example. FIG. 8a is an electron microscope image of the completed gallium nitride pyramid. FIG. 8b is a transmission electron microscope (TEM) image of the sample taken in the incident direction [112̅0], illustrating the sample covered by the SiO₂ insulating layer and the titanium electrode and illustrating the bonding of the hexagonal crystal of the gallium nitride pyramid with the titanium electrode and the gallium nitride layer. FIGS. 8c and 8d are enlarged images of FIG. 8a, wherein a slant face of the gallium nitride hexagonal pyramid is 28°, which matches θ=tan⁻¹ (d₁₁₀₀/d₀₀₀₁), wherein d₁₁₀₀ and d₀₀₀₁ are the length of the M-axis of the gallium nitride and the length of the c-axis of the gallium nitride respectively, showing that the example had a high-quality single crystal structure. FIGS. 8e-8i are high-resolution atomic images of the interfaces of the gallium nitride pyramid and the gallium nitride layer. It was found that the interfaces of the semiconductors had reliably been bonded after the high-temperature annealing. The portion shown in FIG. 8g near the bottom of the center was found to have the best effect, because the interfaces of the two semiconductors could not be identified. FIGS. 8j-8l are SAD images, wherein FIG. 8j is the diffraction pattern of the gallium nitride pyramid; FIG. 8k is the diffraction pattern at the interfaces of the gallium nitride pyramid and the gallium nitride layer, wherein it was found that, given matched lattices of the gallium nitride pyramid and the gallium nitride layer, a diffraction pattern of a single lattice was presented after bonding; and FIG. 8l is a diffraction pattern of the gallium nitride layer, wherein it was proven that, given the same incident direction, the directions of the gallium nitride layer and the gallium nitride pyramid matched with each other. Thus, as can be seen from this sample, a current-voltage curve that should be possessed by a light emitting element can successfully be measured if the lattice directions of the gallium nitride pyramid and the gallium nitride layer match with each other.

By the above technical solutions, the main features of the light emitting element and its manufacturing method according to the present invention are that the large end face 22 of the gallium nitride pyramid 2 contacts with the mounting face 11 of the gallium nitride layer 1, the c-axis of the gallium nitride pyramid 2 is coaxial to the c-axis of the gallium nitride layer 1, the M-plane of the gallium nitride pyramid 2 is parallel to the M-plane of the gallium nitride layer 1, the broken bonds at the large end face 22 of the gallium nitride pyramid 2 and the mounting face 11 of the gallium nitride layer 1 weld with each other, such that the gallium nitride layer 1 and the gallium nitride pyramid 2 of the light emitting element tightly couple with each other to match the lattice of the gallium nitride layer 1 (a P-type semiconductor) with the lattice of the gallium nitride pyramid 2 (an N-type semiconductor), avoiding epitaxial defects in the light emitting element while reinforcing the bonding between the gallium nitride layer 1 and the gallium nitride pyramid 2 to increase the bonding effect, thereby permitting smooth flow of electrons to enhance the electroluminescence effect. The effects of increasing the light emitting efficiency and improving the light emitting stability can, thus, be achieved.

Furthermore, since difficulties in manufacturing of electrodes are encountered in the trend of making the sizes of photoelectric elements smaller, the present invention provides the first electrode 4 covering the gallium nitride pyramid 2 and exposing the smaller end face 21 outside of the insulating layer 3 and provides the second electrode 5 connected to the gallium nitride layer 1 below the insulating layer, such that the first and second electrodes 4 and 5 can easily be manufactured while providing an effective insulating effect, solving the bottleneck in manufacture of the electrodes of nanoscale photoelectric elements.

Thus since the invention disclosed herein may be embodied in other specific forms without departing from the spirit or general characteristics thereof, some of which forms have been indicated, the embodiments described herein are to be considered in all respects illustrative and not restrictive. The scope of the invention is to be indicated by the appended claims, rather than by the foregoing description, and all changes which come within the meaning and range of equivalency of the claims are intended to be embraced therein.

1. A method for manufacturing a light emitting element, comprising:
disposing a gallium nitride layer on a substrate, with the gallium nitride layer including a mounting face, and preparing a gallium nitride pyramid, with the gallium nitride pyramid including a smaller end face and a larger end face;
contacting the larger end face of the gallium nitride pyramid with the mounting face of the gallium nitride layer, with a c-axis of the gallium nitride layer coaxial to a c-axis of the gallium nitride pyramid, and with an M-plane of the gallium nitride layer parallel to an M-plane of the gallium nitride pyramid;
increasing temperatures of the gallium nitride layer and the gallium nitride pyramid and then reducing the temperatures of the gallium nitride layer and the gallium nitride pyramid, with broken bonds at the larger end face of the gallium nitride pyramid and the mounting face of the gallium nitride layer welding with each other;
coating an insulating layer on faces of the gallium nitride layer and the gallium nitride pyramid;
removing a portion of the insulating layer on the faces of the gallium nitride pyramid to form an electrically conductive portion on the gallium nitride pyramid;
disposing a first electrode on the electrically conductive portion of the gallium nitride pyramid;
removing a portion of the insulating layer on the faces of the gallium nitride layer to form an electrically conductive portion on the gallium nitride layer; and
disposing a second electrode on the electrically conductive portion of the gallium nitride layer.

2. The method for manufacturing a light emitting element as claimed in claim 1, wherein the temperatures of the gallium nitride layer and the gallium nitride pyramid are increased to 550-750° C. and then reduced to 25° C. to make the broken bonds at the larger end face of the gallium nitride pyramid and the mounting face of the gallium nitride layer welding with each other.

3. The method for manufacturing a light emitting element as claimed in claim 2, wherein the temperatures of the gallium nitride layer and the gallium nitride pyramid are increased and then kept at the increased temperatures for a period of time before reducing the temperatures of the gallium nitride layer and the gallium nitride pyramid.

4. The method for manufacturing a light emitting element as claimed in claim 1, wherein the gallium nitride layer grows in [0001] direction of a four-axis coordinate system.

5. The method for manufacturing a light emitting element as claimed in claim 1, wherein the gallium nitride pyramid grows in [0001̅] direction of a four-axis coordinate system and forms a prism and a pyramid.

6. The method for manufacturing a light emitting element as claimed in claim 1, wherein the insulating layer is an oxidation layer.

7. The method for manufacturing a light emitting element as claimed in claim 6, wherein the oxidation layer contains aluminum oxide or silicon oxide.

8. The method for manufacturing a light emitting element as claimed in claim 1, wherein the insulating layer has a thickness of 200-300 nm.

9. The method for manufacturing a light emitting element as claimed in claim 1, wherein the first electrode is made of titanium, aluminum, titanium-aluminum alloy, titanium-nickel alloy, or titanium-aluminum-nickel-gold alloy.

10. The method for manufacturing a light emitting element as claimed in claim 1, wherein the second electrode is made of nickel-platinum alloy, nickel-gold alloy, or nickel-platinum-gold alloy.

11. A light emitting element comprising:
a gallium nitride layer including a mounting face;
a gallium nitride pyramid including a smaller end face and a larger end face, with the larger end face of the gallium nitride pyramid contacting with the mounting face of the gallium nitride layer, with a c-axis of the gallium nitride layer coaxial to a c-axis of the gallium nitride pyramid, and with an M-plane of the gallium nitride layer parallel to an M-plane of the gallium nitride pyramid, with broken bonds at the mounting face of the gallium nitride layer and the larger end face of the gallium nitride pyramid welded with each other;
an insulating layer coated on faces of the gallium nitride layer and the gallium nitride pyramid, with a portion of the gallium nitride pyramid exposed outside of the insulating layer to form an electrically conductive portion, with a portion of the gallium nitride layer exposed outside of the insulating layer to form an electrically conductive portion;
a first electrode electrically connected to the electrically conductive portion of the gallium nitride pyramid; and
a second electrode electrically connected to the electrically conductive portion of the gallium nitride layer,
wherein the gallium nitride layer and the gallium nitride pyramid have matched lattices.

12. The light emitting element as claimed in claim 11, wherein the insulating layer is an oxidation layer.

13. The light emitting element as claimed in claim 12, wherein the oxidation layer contains aluminum oxide or silicon oxide.

14. The light emitting element as claimed in claim 11, wherein the insulating layer has a thickness of 200-300 nm.

15. The light emitting element as claimed in claim 11, wherein the first electrode is made of titanium, aluminum, titanium-aluminum alloy, titanium-nickel alloy, or titanium-aluminum-nickel-gold alloy.

16. The light emitting element as claimed in claim 11, wherein the second electrode is made of nickel-platinum alloy, nickel-gold alloy, or nickel-platinum-gold alloy.

17. The light emitting element as claimed in claim 11, wherein the gallium nitride layer grows in [0001] direction of a four-axis coordinate system.

18. The light emitting element as claimed in claim 11, wherein the gallium nitride pyramid grows in [0001̅] direction of a four-axis coordinate system.
